(19) United States
(12) Patent Application Publication
(10) Pub. No.: US 2019/0355649 A1
(43) Pub. Date: Nov. 21, 2019

(54) SEMICONDUCTOR DEVICE

(71) Applicant: TOYOTA JIDOSHA KABUSHIKI KAISHA, Toyota-shi (JP)

(72) Inventor: Takanori KAWASHIMA, Anjo-shi (JP)

(73) Assignee: TOYOTA JIDOSHA KABUSHIKI KAISHA, Toyota-shi (JP)

(21) Appl. No.: 16/398,428

(22) Filed: Apr. 30, 2019

(30) Foreign Application Priority Data
May 15, 2018 (JP) 2018-093955

(51) Int. Cl. H01L 23/495; H01L 23/00; H01L 23/31; H01L 23/34

(52) U.S. Cl. CPC H01L 23/49562; H01L 24/09; H01L 24/49; H01L 23/49568; H01L 2924/13091; H01L 23/3185; H01L 23/34; H01L 2924/13055; H01L 23/49548

(57) ABSTRACT

A semiconductor device may include a first semiconductor module and a second semiconductor module. The first semiconductor module may include a first semiconductor element, a first encapsulant encapsulating the first semiconductor element and first and second power terminals electrically connected with the first semiconductor element within the first encapsulant and extending to outside of the first encapsulant. The second semiconductor module may include a second semiconductor element, a second encapsulant encapsulating the second semiconductor element, and third and fourth power terminals electrically connected with the second semiconductor element within the second encapsulant and extending to outside of the second encapsulant. Outside the first and second encapsulants, the first and fourth power terminals may extend to be opposed to each other, and the second and third power terminals may extend to be opposed to each other.

### CROSS-REFERENCE

This application claims priority to Japanese Patent Application No. 2018-093955, filed on May 15, 2018, the entire contents of which are incorporated herein by reference.

### TECHNICAL FIELD

The technology disclosed herein relates to a semiconductor device including a plurality of semiconductor modules.

### BACKGROUND

Japanese Patent Application Publication No. 2012-235081 describes a semiconductor device including a plurality of semiconductor modules. Each of the semiconductor modules includes one or more semiconductor elements, and a plurality of power terminals connected with the one or more semiconductor elements. The plurality of semiconductor modules is stacked with one another with a cooler interposed between each pair of the semiconductor modules, and their power terminals are electrically connected with one another. A semiconductor device of this type is used, for example, in a power control device and constitutes at least a part of a power conversion circuit such as an inverter or a converter.

### SUMMARY

In a semiconductor device, a surge voltage may occur when a current flowing in the semiconductor device sharply changes. Since the surge voltage could cause, for example, a failure of a semiconductor element or unnecessary power consumption, it is desired to suppress the surge voltage. An effective way to suppress the surge voltage is to reduce an inductance of the semiconductor device. The disclosure herein provides a technology capable of reducing an inductance of a semiconductor device including a plurality of semiconductor modules.

A semiconductor device disclosed herein may comprise a first semiconductor module, and a second semiconductor module stacked with the first semiconductor module. The first semiconductor module may comprise at least one first semiconductor element, a first encapsulant encapsulating the at least one first semiconductor element, a first power terminal electrically connected with an upper electrode of each of the at least one first semiconductor element within the first encapsulant and extending to outside of the first encapsulant, and a second power terminal electrically connected with a lower electrode of each of the at least one first semiconductor element within the first encapsulant and extending to the outside of the first encapsulant. The second semiconductor module may comprise at least one second semiconductor element, a second encapsulant encapsulating the at least one second. semiconductor element, a third power terminal electrically connected with an upper electrode of each of the at least one second semiconductor element within the second encapsulant and extending to outside of the second encapsulant, and a fourth power terminal electrically connected with a lower electrode of each of the at least one second semiconductor element within the second encapsulant and extending to the outside of the second encapsulant. Outside the first encapsulant and the second encapsulant, the first power terminal and the fourth power terminal extend to be opposed to each other, and the second power terminal and the third power terminal extend to be opposed to each other.

In the semiconductor device above, the first power terminal of the first semiconductor module and the fourth power terminal of the second semiconductor module extend to be opposed to each other. Therefore, when currents respectively flow in the first power terminal and the fourth power terminal in reverse directions to each other, a magnetic field formed by the current. in the first power terminal and a magnetic field formed by the current in the fourth power terminal cancel out each other. Due to this, the magnetic fields formed around the first power terminal and the fourth power terminal are suppressed, and an inductance of each of the first power terminal and the fourth power terminal is thereby reduced. Similarly, the second power terminal of the first semiconductor module and the third power terminal of the second semiconductor module extend to be opposed to each other. Therefore, when currents respectively flow in the second power terminal and the third power terminal in reverse directions to each other, a magnetic field formed by the current in the second power terminal and a magnetic field formed by the current in the third power terminal cancel out each other. Due to this, the magnetic fields formed around the second power terminal and the third power terminal are suppressed, and an inductance of each of the second power terminal and the third power terminal is reduced.

In the first semiconductor module, in particular, the first power terminal and the second power terminal are electrically connected with each other via the at least one first semiconductor element, so currents respectively flow in the first power terminal and the second power terminal in reverse directions to each other. Similarly, in the second semiconductor module, the third power terminal and the fourth power terminal are electrically connected with each other via the at least one second semiconductor element, so currents respectively flow in the third power terminal and the fourth power terminal in reverse directions to each other. Therefore, when currents respectively flow in the first power terminal of the first semiconductor module and the fourth power terminal of the second semiconductor module in reverse directions to each other, currents also respectively flow in the second power terminal of the first semiconductor module and the third power terminal of the second semiconductor module in reverse directions to each other. Due to this, reduction in the inductance of each of the first power terminal and the fourth power terminal takes place at the same time as reduction in the inductance of each of the second power terminal and the third power terminal, by which an impedance of the semiconductor device can be effectively reduced.

### BRIEF DESCRIPTION OF DRAWINGS

FIG. 1 is an external view of a semiconductor device 2.

FIG. 2 is an external view of a first semiconductor module 10.

FIG. 3 is a diagram showing a cross-sectional structure of the first semiconductor module 10.

FIG. 4 is a plan view showing an internal structure of the first semiconductor module 10 with a first encapsulant 16 omitted.

FIG. 5 is an exploded view showing the internal structure of the first semiconductor module 10 with the first encapsulant 16 omitted.

FIG. 6 is an external view of a second semiconductor module 50.

FIG. 7 shows a cross-sectional structure of the second semiconductor module 50.

FIG. 8 is a plan view showing an internal structure of the second semiconductor module 50 with a second encapsulant 56 omitted.

FIG. 9 is an exploded view showing the internal structure of the second semiconductor module 50 with the second encapsulant 56 omitted.

FIG. 10 shows a circuit structure of the semiconductor device 2.

FIG. 11 shows a variant in which an opening 42 is provided in a first conductor plate 12.

FIG. 12 shows a variant in which an opening 44 is provided in a second conductor plate 14.

### DETAILED DESCRIPTION

In an embodiment of the present technology, the first semiconductor module and the second semiconductor module may be arranged such that the upper electrode of each of the at least one first semiconductor element is opposed to the upper electrode of each of the at least one second semiconductor element or such that the lower electrode of each of the at least one first semiconductor element is opposed to the lower electrode of each of the at least one second semiconductor element. Such a configuration enables the first semiconductor module and the second semiconductor module to have a same structure or similar structures with respect to each other.

In an embodiment of the present technology, the at least one first semiconductor element of the first semiconductor module may include a plurality of first semiconductor elements, and the at least one second semiconductor element of the second semiconductor module may include a plurality of second semiconductor elements. In other words, the present technology can be applied to various semiconductor devices and produce similar effects, regardless of the number of semiconductor elements.

In an embodiment of the present technology, the first power terminal and the second power terminal may be symmetrically arranged in the first semiconductor module, and the third power terminal and the fourth power terminal may be symmetrically arranged in the second semiconductor module. Such a configuration enables the first semiconductor module and the second semiconductor module to he stacked with each other compactly.

In an embodiment of the present technology, the first semiconductor module and the second semiconductor module may have a same structure and may be arranged in inverted orientations with respect to each other. In such a configuration, the two semiconductor modules have the same structure, by which costs for manufacturing the semiconductor device, for example, can be reduced.

In an embodiment of the present technology, the first power terminal and the fourth power terminal may be electrically connected with each other, and the at least one first semiconductor element and the at least one second semiconductor element may be electrically connected in series between the second power terminal and the third power terminal. Such a configuration enables the first semiconductor module and the second semiconductor module to constitute upper and lower arms in an inverter or a converter. In this case, the second power terminal and the third power terminal may be configured to be connected with a capacitor to suppress fluctuations in voltage and/or current.

In an embodiment of the present technology, the first semiconductor module may further comprise a first conductor plate, and a second conductor plate opposed to the first conductor plate with the at least one first semiconductor element interposed therebetween. In this case, the first conductor plate may be electrically connected with the upper electrode of each of the at least one first semiconductor element and may be electrically connected with the first power terminal, and the second conductor plate may be electrically connected with the lower electrode of each of the at least one first semiconductor element and may be electrically connected with the second power terminal. Similarly, the second semiconductor module may further comprise a third conductor plate, and a fourth conductor plate opposed to the third conductor plate with the at least one second semiconductor element interposed therebetween. In this case, the third conductor plate may be electrically connected with the upper electrode of each of the at least one second semiconductor element and may be electrically connected with the third power terminal, and the fourth conductor plate may be electrically connected with the lower electrode of each of the at least one second semiconductor element and may be electrically connected with the fourth power terminal.

In the embodiment above, in the first semiconductor module, the first power terminal may be joined on a lower surface of the first conductor plate, the lower surface of the first conductor plate may be opposed to the second conductor plate, and the second conductor plate may include a notch at a region opposed to the first power terminal. Such a configuration enables the first conductor plate and the second conductor plate to be opposed to each other over a large area while maintaining insulation between the first power terminal and the second conductor plate, by which an impedance of the first semiconductor module can be reduced.

In addition to or in place of the above, in the second semiconductor module, the third power terminal may be joined on a lower surface of the third conductor plate, the lower surface of the third conductor plate may be opposed to the fourth conductor plate, and the fourth conductor plate may comprise a notch at a region opposed to the third power terminal. Such a configuration enables the third conductor plate and the fourth conductor plate to be opposed to each other over a large area while maintaining insulation between the third power terminal and the fourth conductor plate, by which an impedance of the second semiconductor module can be reduced.

In the embodiment above, at least one of the first conductor plate and the second conductor plate of the first semiconductor module may comprise an opening. In this case, the opening may be located between the first power terminal and the at least one first semiconductor element, or between the second power terminal and the at least one first semiconductor element. Such a configuration can suppress current concentration to a particular semiconductor element by causing a current flowing in the first conductor plate or the second conductor plate to detour around the opening.

In addition to or in place of the above, at least one of the third conductor plate and the fourth conductor plate of the second semiconductor module may comprise an opening. In this case, the opening may be located between the third power terminal and the at least one second semiconductor element, or between the fourth power terminal and the at least one second semiconductor element. Such a configuration can suppress current concentration to a particular semiconductor element by causing a current flowing in the third conductor plate or the fourth conductor plate to detour around the opening.

In an embodiment of the present technology, each of the at least one first semiconductor element and the at least one second semiconductor element may be a switching element, for example, an insulated gate bipolar transistor (IGBT) or a metal-oxide-semiconductor field-effect transistor (MOSFET). In this case, each of the upper electrodes of the at least one first semiconductor element and the at least one second semiconductor element may be an emitter electrode of the IGBT or a source electrode of the MOSFET, and each of the lower electrodes of the at least one first semiconductor element and the at least one second semiconductor element may be a collector electrode of the IGBT or a drain electrode of the MOSFET.

Representative, non-limiting examples of the present disclosure will now be described in further detail with reference to the attached drawings. This detailed description is merely intended to teach a person of skill in the art further details for practicing aspects of the present teachings and is not intended to limit the scope of the present disclosure. Furthermore, each of the additional features and teachings disclosed below may be utilized separately or in conjunction with other features and teachings to provide improved semiconductor devices, as well as methods for using and manufacturing the same.

Moreover, combinations of features and steps disclosed in the following detailed description may not be necessary to practice the present disclosure in the broadest sense, and are instead taught merely to particularly describe representative examples of the disclosure. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

With reference to the drawings, a semiconductor device 2 in an embodiment will be described. The semiconductor device 2 is adopted far a power control device, for example, in an electric vehicle and can constitute at least a part of a power conversion circuit such as a converter or an inverter. The electric vehicle herein widely refers to vehicles with a motor that drives wheels. Examples of the electric vehicle include an electric vehicle charged with external power, a hybrid vehicle that includes an engine in addition to a motor, a fuel-cell vehicle powered by a fuel cell, and the like.

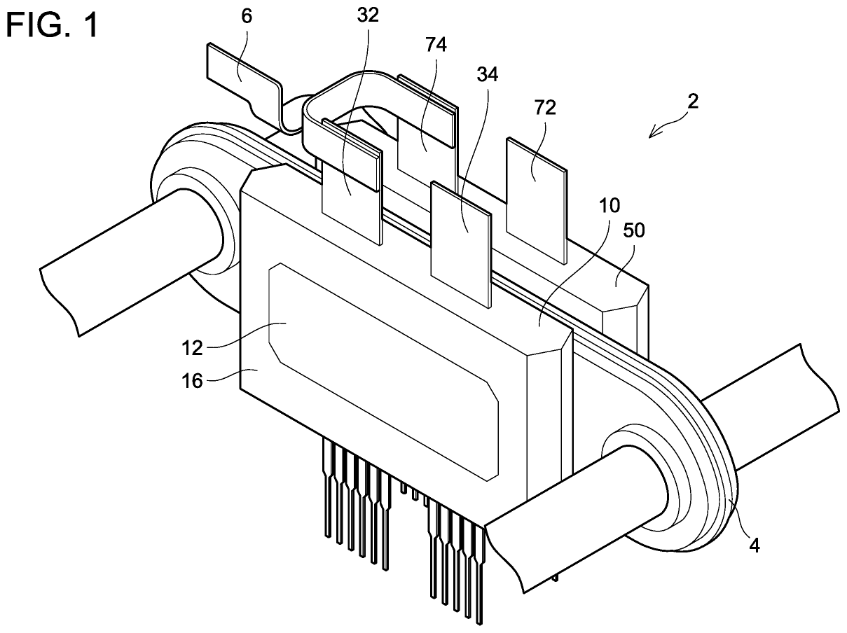

As shown in FIG. 1, the semiconductor device 2 includes a first semiconductor module 10 and a second semiconductor module 50. The second semiconductor module 50 is stacked with the first semiconductor module 10. A cooler 4 is arranged between the first semiconductor module 10 and the second semiconductor module 50. The semiconductor device 2 may include more semiconductor modules, in addition to the first semiconductor module 10 and the second semiconductor module 50. In this case, the semiconductor device 2 may include a structure in which the combination of the first semiconductor module 10 and the second semiconductor module 50, which are to be described later, is repeatedly arranged with the cooler 4 interposed between each pair of the first semiconductor module 10 and the second semiconductor module 50.

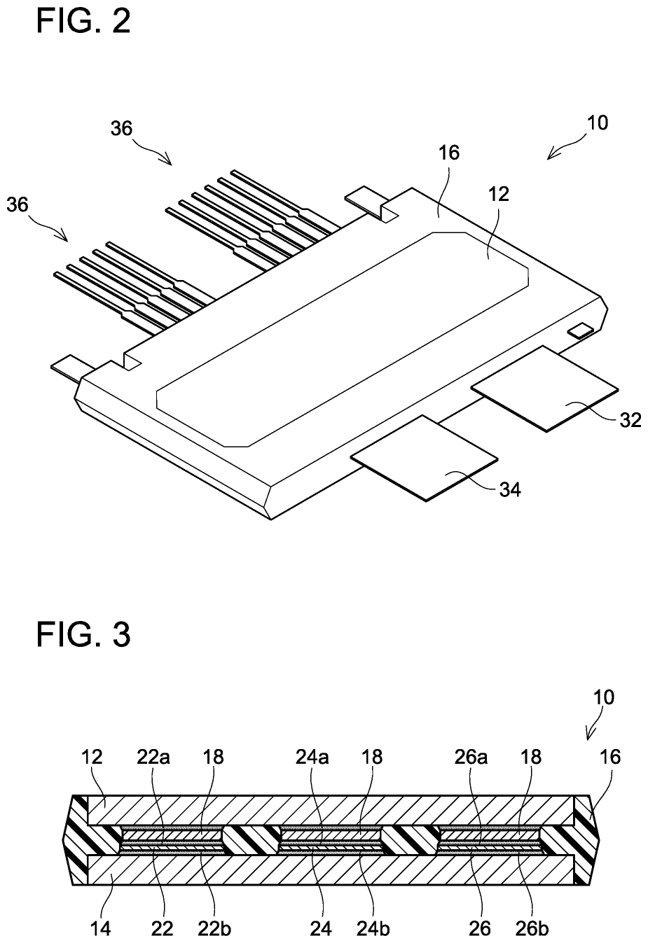

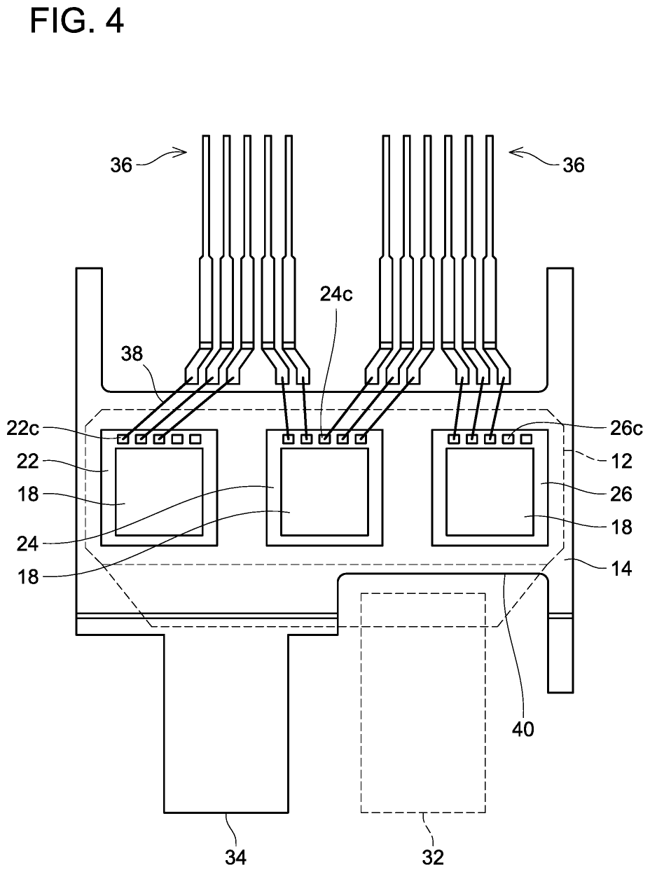

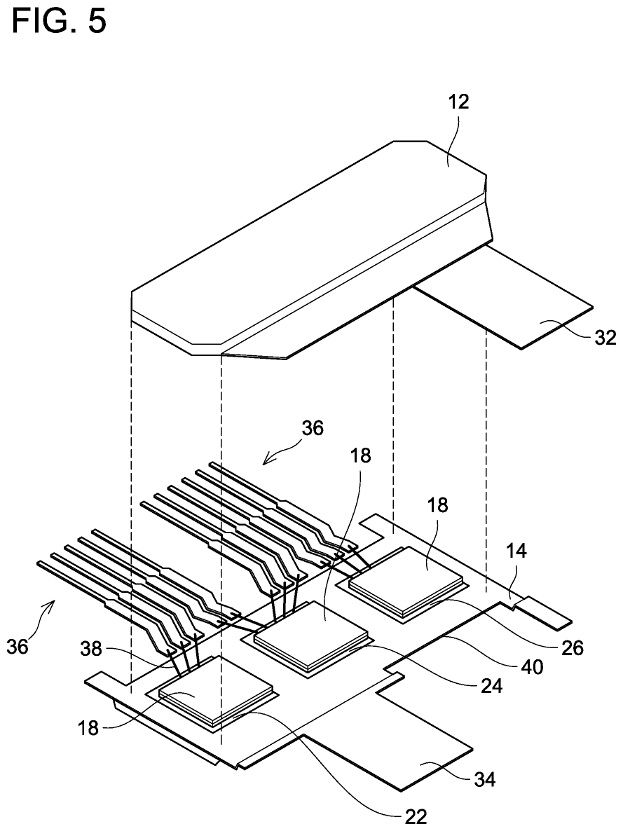

As shown in FIGS. 2 to 5, the first semiconductor module 10 includes a first conductor plate 12, a second conductor plate 14, a plurality of first semiconductor elements 22, 24, 26, and a first encapsulant 16. The first conductor plate 12 and the second conductor plate 14 are parallel to each other and are opposed to each other. The plurality of first semiconductor elements 22, 24, 26 is located between the first conductor plate 12 and the second conductor plate 14. The plurality of first semiconductor elements 22, 24, 26 is linearly arranged along a longitudinal direction of the first conductor plate 12 and the second conductor plate 14 (in a left-right direction in FIGS. 3 and 4). The plurality of first semiconductor elements 22, 24, 26 is encapsulated by the first encapsulant 16.

Each of the first conductor plate 12 and the second conductor plate 14 is constituted of a conductor such as copper or another metal. Each of the first semiconductor elements 22, 24, 26 is connected not only with the first conductor plate 12 but also with the second conductor plate 14. The first semiconductor elements 22, 24, 26 are thereby connected in parallel with one another between the first conductor plate 12 and the second conductor plate 14. A conductor spacer 18 is provided between each of the first semiconductor elements 22, 24, 26 and the first conductor plate 12. Here, a specific configuration of each of the first conductor plate 12 and the second conductor plate 14 is not particularly limited. For example, at least one of the first conductor plate 12 and the second conductor plate 14 may be an insulated substrate that includes an intermediate layer constituted of an insulator (e.g., ceramic), such as a direct bonded copper (DBC) substrate. In other words, each of the first conductor plate 12 and the second conductor plate 14 may not necessarily be constituted of a conductor over its entirety.

The first semiconductor elements 22, 24, 26 are each a so-called power semiconductor element for a power circuit and have a same configuration with respect to one another. The first semiconductor elements 22, 24, 26 respectively include upper electrodes 22a, 24a, 26a; lower electrodes 22b, 24b, 26b; and pluralities of signal pads 22c, 24c, 26c. Each of the upper electrodes 22a, 24a, 26a and the lower electrodes 22b, 24b, 26b is an electrode for power, and each of the pluralities of signal pads 22c, 24c, 26c is an electrode for signal. The upper electrodes 22a, 24a, 26a and the pluralities of signal pads 22c, 24c, 26c are respectively located on upper surfaces of the first semiconductor elements 22, 24, 26, and the lower electrodes 22b, 24b, 26b are respectively located on lower surfaces of the first semiconductor elements 22, 24, 26. The upper electrodes 22a, 24a, 26a are joined to the first conductor plate 12 via the conductor spacers 18, and the lower electrodes 22b, 24b, 26b are joined to the second conductor plate 14.

As an example, each of the first semiconductor elements 22, 24, 26 in the present embodiment is a switching element, and specifically includes an IGBT structure that includes an emitter and a collector. Each of the emitters of the IGBT structures is connected with corresponding one of the upper electrodes 22a, 24a, 26a, and each of the collectors of the IGBT structures is connected with corresponding one of the lower electrodes 22b, 24b, 26b. It should be noted that a specific type and structure of each of the first semiconductor elements 22, 24, 26 are not particularly limited. Each of the first semiconductor elements 22, 24, 26 may be a reverse conducting (RC)-IGBT element that further includes a diode structure. Alternatively, each of the first semiconductor elements 22, 24, 26 may include, for example, a MOSFET structure, in place of or in addition to the IGBT structure. In this case, each of sources of the MOSFET structures may be connected with corresponding one of the upper electrodes 22a, 24a, 26a, and each of drains of the MOSFET structures may be connected with corresponding one of the lower electrodes 22b, 24b, 26b. Moreover, a semiconductor material used for each of the first semiconductor elements 22, 24, 26 is not particularly limited, and it may be, for example, silicon (Si), silicon carbide (SiC), or a nitride semiconductor such as gallium nitride (GaN).

The first encapsulant 16 can be constituted of, for example, a thermosetting resin such as epoxy resin or another insulator, although no particular limitation is placed thereon. The first encapsulant 16 is also termed, for example, a molded resin or a package. Here, a number of the first semiconductor elements 22, 24, 26 is not particularly limited. In the present embodiment, the first semiconductor module 10 includes the three first semiconductor elements 22, 24, 26, however, in another embodiment, the first semiconductor module 10 only needs to include at least one first semiconductor element.

The first conductor plate and the second conductor plate 14 are connected with the plurality of first semiconductor elements 22, 24, 26, not only electrically but also thermally. Moreover, each of the first conductor plate 12 and the second conductor plate 14 is exposed at a surface of the first encapsulant 16, and can dissipate heat of the first semiconductor elements 22, 24, 26 to outside of the first encapsulant 16. As such, the first semiconductor module 10 in the present embodiment includes a double-sided cooling structure in which heat-dissipating plates are arranged respectively on both sides of the plurality of first semiconductor elements 22, 24, 26.

The first semiconductor module 10 further includes a first power terminal 32, a second power terminal 34, and a plurality of first signal terminals 36. Each of the terminals 32, 34, 36 is constituted of a conductor such as copper or aluminum, and extends from inside to outside of the first encapsulant 16. The first power terminal 32 is connected with the first conductor plate 12 within the first encapsulant 16. The second power terminal 34 is connected with the second conductor plate 14 within the first encapsulant 16. Due to this, the plurality of first semiconductor elements 22, 24, 26 is electrically connected in parallel between the first power terminal 32 and the second power terminal 34. Each of the first signal terminals 36 is connected with corresponding one of the signal pads 22c, 24c, 26c of the first semiconductor elements 22, 24, 26 via a bonding wire 38.

Each of the first power terminal 32 and the second power terminal 34 has a plate shape, and they protrude from the first encapsulant 16 in a same direction. The first power terminal 32 and the second power terminal 34 are located on a same plane and extend in parallel with each other. The first power terminal 32 and the second power terminal 34 are symmetrically arranged. As an example, the first power terminal 32 is joined to the first conductor plate 12 by soldering, and the second power terminal 34 is configured integrally with the second conductor plate 14. It should be noted that the first power terminal 32 may be configured integrally with the first conductor plate 12. Moreover, the second power terminal 34 may be configured as a member separate from the second conductor plate 14 and may be joined to the second conductor plate 14 by, for example, soldering. Furthermore, each of the first signal terminals 36 may be directly connected with corresponding one of the signal pads 22c, 24c, 26c, without intervention of the bonding wires 38.

In the first semiconductor module 10 in the present embodiment, the first power terminal 32 is joined on a lower surface of the first conductor plate 12 and the lower surface of the first conductor plate 12 is opposed to the second conductor plate 14. The second conductor plate 14 includes a notch 40 at a region opposed to the first power terminal 32. Such a configuration enables the first conductor plate 12 and the second conductor plate 14 to be opposed to each other over a large area while maintaining insulation between the first power terminal 32 and the second conductor plate 14, by which an impedance of the first semiconductor module 10 can be reduced.

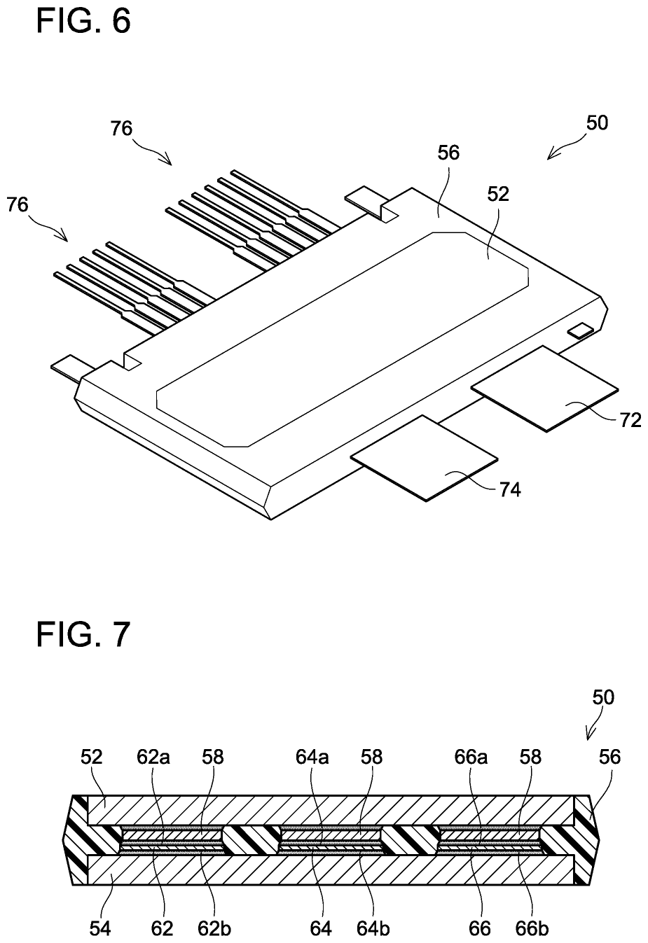

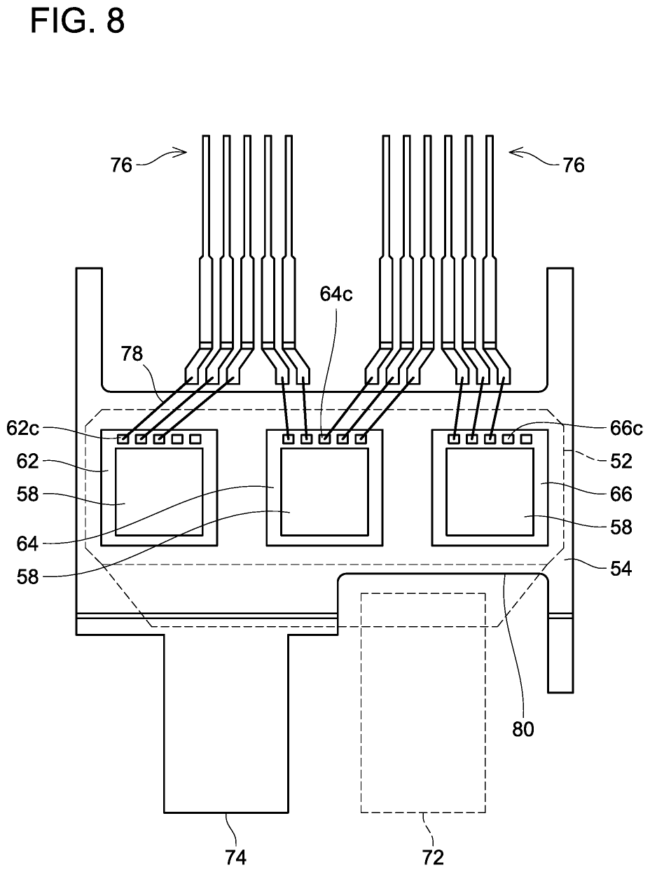

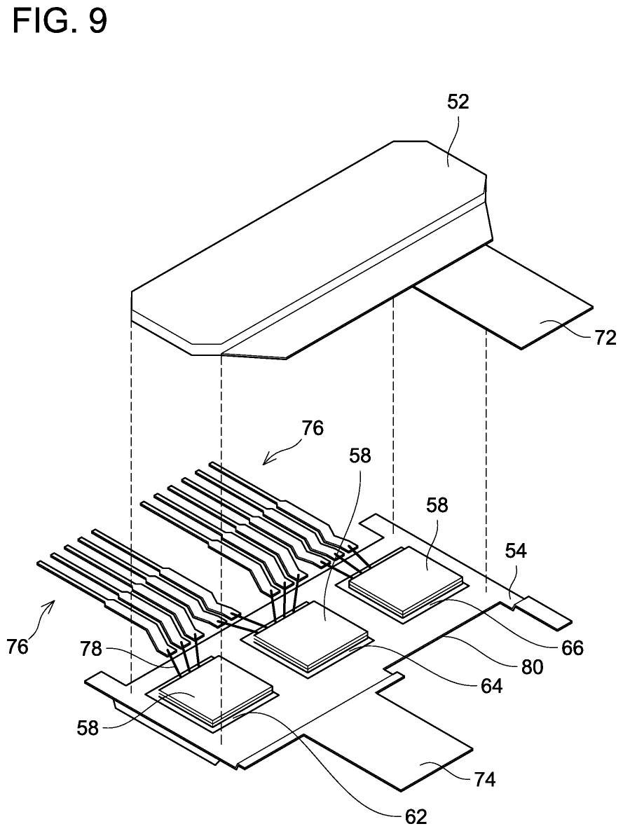

Next, with reference to FIGS. 6 to 9, the second semiconductor module 50 will be described. As shown in FIGS. 6 to 9, the second semiconductor module 50 includes a third conductor plate 52, a fourth conductor plate 54, a plurality of second semiconductor elements 62, 64, 66, and a second encapsulant 56. The third conductor plate 52 and the fourth conductor plate 54 are parallel to each other and are opposed to each other. The plurality of second semiconductor elements 62, 64, 66 is located between the third conductor plate 52 and the fourth conductor plate 54. The plurality of second semiconductor elements 62, 64, 66 is linearly arranged along a longitudinal direction of the third conductor plate 52 and the fourth conductor plate 54 (along a left-right direction in FIGS. 7 and 8). The plurality of second semiconductor elements 62, 64, 66 is encapsulated by the second encapsulant 56.

Each of the third conductor plate 52 and the fourth conductor plate 54 is constituted of a conductor such as copper or another metal. Each of the second semiconductor elements 62, 64, 66 is connected not only with the third conductor plate 52 but also with the fourth conductor plate 54. Due to this, the second semiconductor elements 62, 64, 66 are connected in parallel with one another between the third conductor plate 52 and the fourth conductor plate 54. A conductor spacer 58 is provided between each of the second semiconductor elements 62, 64, 66 and the third conductor plate 52. Here, a specific configuration of each of the third conductor plate 52 and the fourth conductor plate 54 is not particularly limited. For example, at least one of the third conductor plate 52 and the fourth conductor plate 54 may be an insulated substrate that includes an intermediate layer constituted of an insulator (e.g., ceramic), such as a direct bonded copper (DBC) substrate. In other words, each of the third conductor plate 52 and the fourth conductor plate 54 may not necessarily be constituted of a conductor over its entirety.

The second semiconductor elements 62, 64, 66 are each a so-called power semiconductor element for a power circuit and have a same configuration with respect to one another. The second semiconductor elements 62, 64, 66 respectively include upper electrodes 62a, 64a, 66a; lower electrodes 62b, 64b, 66b; and pluralities of signal pads 62c, 64c, 66c. Each of the upper electrodes 62a, 64a, 66a and the lower electrodes 62b, 64b, 66b is an electrode for power, and each of the pluralities of signal pads 62c, 64c, 66c is an electrode for signal. The upper electrodes 62a, 64a, 66a and the pluralities of signal pads 62c, 64c, 66c are respectively located on upper surfaces of the second semiconductor elements 62, 64, 66, and the lower electrodes 62b, 64b, 66b are respectively located on lower surfaces of the second semiconductor elements 62, 64, 66. The upper electrodes 62a, 64a, 66a are joined to the third conductor plate 52 via the conductor spacers 58, and the lower electrodes 62b, 64b, 66b are joined to the fourth conductor plate 54.

As an example, each of the second semiconductor elements 62, 64, 66 in the present embodiment is a switching element, and specifically includes an IGBT structure that includes an emitter and a collector. Each of the emitters of the IGBT structures is connected with corresponding one of the upper electrodes 62a, 64a, 66a, and each of the collectors of the IGBT structures is connected with corresponding one of the lower electrodes 62b, 64b, 66b. It should be noted that a specific type and structure of each of the second semiconductor elements 62, 64, 66 are not particularly limited. Each of the second semiconductor elements 62, 64, 66 may be an RC-IGBT element that further includes a diode structure. Alternatively, each of the second semiconductor elements 62, 64, 66 may include, for example, a MOSFET structure, in place of or in addition to the IGBT structure. In this case, each of sources of the MOSFET structures may be connected with corresponding one of the upper electrodes 62a, 64a, 66a, and each of drains of the MOSFET structures may be connected with corresponding one of the lower electrodes 62b, 64b, 66b. Moreover, a semiconductor material used for each of the second semiconductor elements 62, 64, 66 is not particularly limited, and it may be, for example, silicon (Si), silicon carbide (SiC), or a nitride semiconductor such as gallium nitride (GaN).

The second encapsulant 56 can be constituted of, for example, a thermosetting resin such as epoxy resin or another insulator, although no particular limitation is placed thereon. The second encapsulant 56 is also termed, for example, a molded resin or a package. Here, a number of the second semiconductor elements 62, 64, 66 is not particularly limited. In the present embodiment, the second semiconductor module 50 includes the three second semiconductor elements 62, 64, 66, however, in another embodiment, the second semiconductor module 50 only needs to include at least one second semiconductor element.

The third conductor plate 52 and the fourth conductor plate 54 are connected with the plurality of second semiconductor elements 62, 64, 66, not only electrically hut also thermally. Moreover, each of the third conductor plate 52 and the fourth conductor plate 54 is exposed at a surface of the second encapsulant 56, and can dissipate heat of the second semiconductor elements 62, 64, 66 to outside of the second encapsulant 56. As such, the second semiconductor module 50 in the present embodiment includes a double-sided cooling structure in which heat-dissipating plates are arranged respectively on both sides of the plurality of second semiconductor elements 62, 64, 66.

The second semiconductor module 50 further includes a third power terminal 72, a fourth power terminal 74, and a plurality of second signal terminals 76. Each of the terminals 72, 74, 76 is constituted of a conductor such as copper or aluminum and extends from inside to outside of the second encapsulant 56. The third power terminal 72 is connected with the third conductor plate 52 within the second encapsulant 56. The fourth power terminal 74 is connected with the fourth conductor plate 54 within the second encapsulant 56. Due to this, the plurality of second semiconductor elements 62, 64, 66 is electrically connected in parallel between the third power terminal 72 and the fourth power terminal 74. Each of the second signal terminals 76 is connected with corresponding one of the signal pads 62c, 64c, 66c of the second semiconductor elements 62, 64, 66 via a bonding wire 78.

Each of the third power terminal 72 and the fourth power terminal 74 has a plate shape, and they protrude from the second encapsulant 56 in a same direction. The third power terminal 72 and the fourth power terminal 74 are symmetrically arranged. The third power terminal 72 and the fourth power terminal 74 are located on a same plane and extend in parallel with each other. As an example, the third power terminal 72 is joined to the third conductor plate 52 by soldering, and the fourth power terminal 74 is configured integrally with the fourth conductor plate 54. It should be noted that the third power terminal 72 may be configured integrally with the third conductor plate 52. Moreover, the fourth power terminal 74 may be configured as a member separate from the fourth conductor plate 54, and may be joined to the fourth conductor plate 54 by, for example, soldering. Furthermore, each of the second signal terminals 76 may be directly connected with corresponding one of the signal pads 62c, 64c, 66c, without intervention of the bonding wires 78.

In the second semiconductor module 50 in the present embodiment, the third power terminal 72 is joined on a lower surface of the third conductor plate 52 and the lower surface of the third conductor plate 52 is opposed to the fourth conductor plate 54. The fourth conductor plate 54 includes a notch 80 at a region opposed to the third power terminal 72. Such a configuration enables the third conductor plate 52 and the fourth conductor plate 54 to be opposed to each other over a large area while maintaining insulation between the third power terminal 72 and the fourth conductor plate 54, by which an impedance of the second semiconductor module 50 can be reduced.

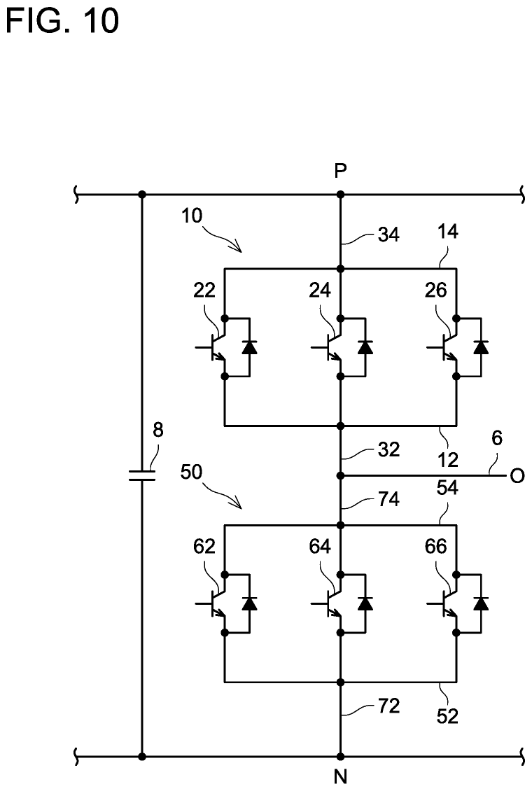

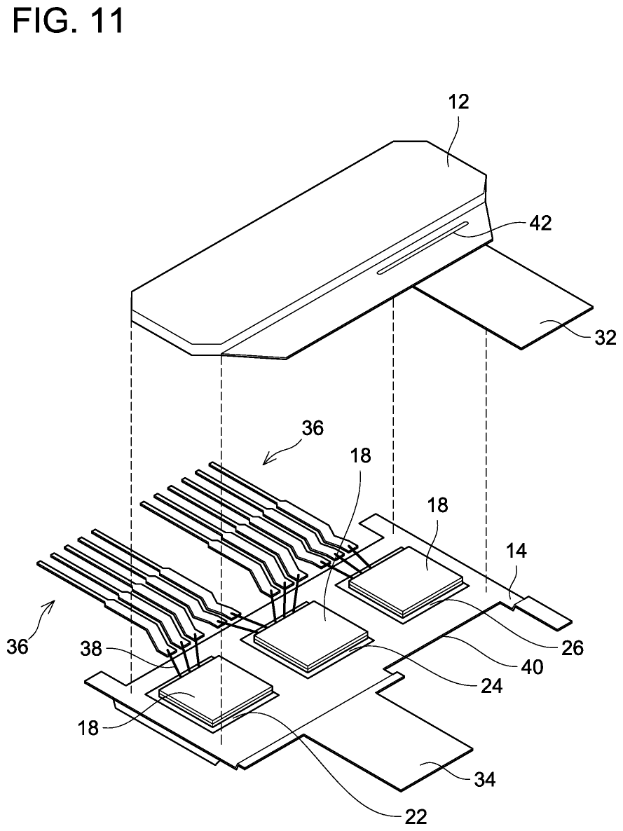

As shown in FIGS. 1 and 10, the first power terminal 32 of the first semiconductor module 10 and the fourth power terminal 74 of the second semiconductor module 50 are electrically connected with each other by a bus bar 6. Due to this, the plurality of first semiconductor elements 22, 24, 26 and the plurality of second semiconductor elements 62, 64, 66 are connected in series between the second power terminal 34 of the first semiconductor module 10 and the third power terminal 72 of the second semiconductor module 50. Such a circuit structure can constitute a pair of upper and lower arms in a power conversion circuit such as a converter or an inverter. In this case, as shown in FIG. 10, the second power terminal 34 of the first semiconductor module 10 and the third power terminal 72 of the second semiconductor module 50 may be connected with a capacitor 8.

As shown in FIG. 1, the first power terminal 32 of the first semiconductor module 10 and the fourth power terminal 74 of the second semiconductor module 50 extend to be opposed to each other outside the first encapsulant 16 and the second encapsulant 56. Therefore, when currents respectively flow in the first power terminal 32 and the fourth power terminal 74 in reverse directions to each other, a magnetic field formed by the current in the first power terminal 32 and a magnetic field formed by the current in the fourth power terminal 74 cancel out each other. Due to this, the magnetic fields formed around the first power terminal 32 and the fourth power terminal 74 are suppressed, and an inductance of each of the first power terminal 32 and the fourth power terminal 74 is reduced.

Similarly, the second power terminal 34 of the first semiconductor module 10 and the third power terminal 72 of the second semiconductor module 50 extend to be opposed to each other outside the first encapsulant 16 and the second encapsulant 56. Therefore, when currents respectively flow in the second power terminal 34 and the third power terminal 72 in reverse directions to each other, a magnetic field formed by the current in the second power terminal 34 and a magnetic field formed by the current in the third power terminal 72 cancel out each other. Due to this, the magnetic fields formed around the second power terminal 34 and the third power terminal 72 are suppressed, and an inductance of each of the second power terminal 34 and the third power terminal 72 is reduced.

In the first semiconductor module 10, in particular, the first power terminal 32 and the second power terminal 34 are electrically connected with each other via the first semiconductor elements 22, 24, 26, so currents flow in the first power terminal 32 and the second power terminal 34 in reverse directions to each other. Similarly, in the second semiconductor module 50, the third power terminal 72 and the fourth power terminal 74 are electrically connected with each other via the second semiconductor elements 62, 64, 66, so currents flow in the third power terminal 72 and the fourth power terminal 74 in reverse directions to each other. Therefore, when currents in reverse directions flow in the first power terminal 32 of the first semiconductor module 10 and the fourth power terminal 74 of the second semiconductor module 50, currents in reverse directions also flow in the second power terminal 34 of the first semiconductor module 10 and the third power terminal 72 of the second semiconductor module 50. Thus, inductances in all of the four power terminals 32, 34, 72, 74 are reduced simultaneously. The effective reduction in impedance of the semiconductor device 2 can suppress surge voltage at switching of the first semiconductor elements 22, 24, 26 and the second semiconductor elements 62, 64, 66.

In the semiconductor device 2 in the present embodiment, the first semiconductor module 10 and the second semiconductor module 50 have the same structure and are arranged in inverted orientations with respect to each other. In other words, the first semiconductor module 10 and the second semiconductor module 50 are stacked such that the lower electrodes 22b, 24b, 26b of the first semiconductor elements 22, 24, 26 are opposed to the lower electrodes 62b, 64b, 66b of the second semiconductor elements 62, 64, 66. It should be noted that, in another embodiment, the first semiconductor module 10 and the second semiconductor module 50 may be stacked such that the upper electrodes 22a, 24a, 26a of the first semiconductor elements 22, 24, 26 are opposed to the upper electrodes 62a, 64a, 66a of the second semiconductor elements 62, 64, 66.

In the semiconductor device 2 in the present embodiment, the first semiconductor module 10 and the second semiconductor module 50 have the same structure. With the two semiconductor modules 10, 50 having the same structure, costs for manufacturing the semiconductor device 2 can be reduced, for example. It should be noted that the two semiconductor modules 10, 50 do not necessarily need to have the same structure, and they may have structures different from each other. For example, the number of the first semiconductor elements 22, 24, 26 included in the first semiconductor module 10 and the number of the second semiconductor elements 62, 64, 66 included in the second semiconductor module 50 may differ from each other.

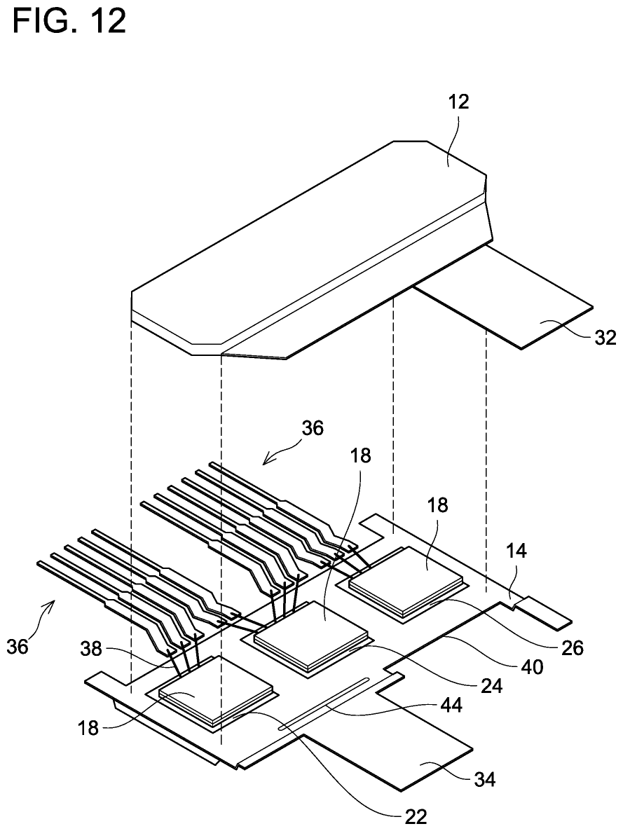

As shown in FIG. 11, the first conductor plate 12 may include an opening 42. This opening 42 is located between the first power terminal 32 and the plurality of first semiconductor elements 22, 24, 26. The opening 42 in the first conductor plate 12 is provided for uniformizing currents that flow in the three first semiconductor elements 22, 24, 26. In other words, distances from the first power terminal 32 to each of the first semiconductor elements 22, 24, 26 are not completely equal. For example, the first semiconductor element 22, which is located on a left side among the plurality of first semiconductor elements 22, 24, 26, is located relatively apart from the first power terminal 32, and the first semiconductor element 26, which is located on a right side among the plurality of first semiconductor elements 22, 24, 26, is located relatively close to the first power terminal 32. Such a distance difference causes difference in electrical resistance, and hence it causes difference in the currents that respectively flow in the first semiconductor elements 22, 24, 26.

For this problem, the first conductor plate 12 includes the opening 42. The opening 42 can reduce the above-described distance difference by partly restricting a current path. The position and shape of the opening 42 may be designed as appropriate, so as to reduce differences in the distances from the first power terminal 32 to each of the first semiconductor elements 22, 24, 26. It should be noted that at least a part of the opening 42 may be located between the first power terminal 32 and the first semiconductor element 26, which is closest to the first power terminal 32 among the plurality of first semiconductor elements 22, 24, 26. Moreover, the opening 42 may be a through hole or may be a bottomed hole (i.e., a recess). Such opening 42 may be provided in the third conductor plate 52 of the second semiconductor module 50 in place of or in addition to being provided in the first conductor plate 12 of the first semiconductor module 10.

In addition to or in place of the above, the second conductor plate 14 may include an opening 44 as shown in FIG. 12. When the second conductor plate 14 includes the opening 44, the currents that flow in to three first semiconductor elements 22, 24, 26 can be uniformized, Similarly to the opening 42 in the first conductor plate 12, the position and shape of the opening 44 in the second conductor plate 14 can be designed as appropriate. It should be noted that at least a part of the opening 44 may be located between the second power terminal 34 and the first semiconductor element 22, which is closest to the second power terminal 34 among the plurality of first semiconductor elements 22, 24, 26. Moreover, the opening 44 may be a through hole or may be a bottomed hole (i.e., a recess). Such opening 44 may be provided in the fourth conductor plate 54 of the second semiconductor module 50 in place of or in addition to being provided in the second conductor plate 14 of the first semiconductor module 10.

What is claimed is:

1. A semiconductor device comprising:
a first semiconductor module; and
a second semiconductor module stacked with the first semiconductor module,
wherein
the first semiconductor module comprises:
at least one first semiconductor element;
a first encapsulant encapsulating the at least one first semiconductor element;
a first power terminal electrically connected with an upper electrode of each of the at least one first semiconductor element within the first encapsulant and extending to outside of the first encapsulant; and
a second power terminal electrically connected with a lower electrode of each of the at least one first semiconductor element within the first encapsulant and extending to the outside of the first encapsulant,
the second semiconductor module comprises:
at least one second semiconductor element;
a second encapsulant encapsulating the at east one second semiconductor element;
a third power terminal electrically connected with an upper electrode of each of the at least one second semiconductor element within the second encapsulant and extending to outside of the second encapsulant; and
a fourth power terminal electrically connected with a lower electrode of each of the at least one second semiconductor element within the second encapsulant and extending to the outside of the second encapsulant, and
outside the first encapsulant and the second encapsulant, the first power terminal and the fourth power terminal extend to be opposed to each other, and the second power terminal and the third power terminal extend to be opposed to each other.

2. The semiconductor device according to claim 1, wherein
the first semiconductor module and the second semiconductor module are arranged such that the upper electrode of each of the at least one first semiconductor element is opposed to the upper electrode of each of the at least one second semiconductor element or such that the lower electrode of each of the at least one first semiconductor element is opposed to the lower electrode of each of the at least one second semiconductor element.

3. The semiconductor device according to claim 1, wherein
the at least one first semiconductor element of the first semiconductor module includes a plurality of first semiconductor elements, and
the at least one second semiconductor element of the second semiconductor module includes a plurality of second semiconductor elements.

4. The semiconductor device according to claim 1, wherein
the first power terminal and the second power terminal are symmetrically arranged in the first semiconductor module, and
the third power terminal and the fourth power terminal are symmetrically arranged in the second semiconductor module.

5. The semiconductor device according to claim 1, wherein the first semiconductor module and the second semiconductor module have a same structure and are arranged in inverted orientations with respect to each other.

6. The semiconductor device according to claim 1, wherein
the first power terminal and the fourth power terminal are electrically connected with each other, and
the at least one first semiconductor element and the least one second semiconductor element are electrically connected in series between the second power terminal and the third power terminal.

7. The semiconductor device according to claim 6, wherein the second power terminal and the third power terminal are configured to be connected with a capacitor.

8. The semiconductor device according to claim 1, wherein
the first semiconductor module further comprises a first conductor plate, and a second conductor plate opposed to the first conductor plate with the at least one first semiconductor element interposed therebetween,
the first conductor plate is electrically connected with the upper electrode of each of the at least one first semiconductor element and is electrically connected with the first power terminal,
the second conductor plate is electrically connected with the lower electrode of each of the at least one first semiconductor element and is electrically connected with the second power terminal,
the second semiconductor module further comprises a third conductor plate, and a fourth conductor plate opposed to the third conductor plate with the at least one second semiconductor element interposed therebetween,
the third conductor plate is electrically connected with the upper electrode of each of the at least one second semiconductor element and is electrically connected with the third power terminal, and
the fourth conductor plate is electrically connected with the lower electrode of each of the at least one second semiconductor element and is electrically connected with the fourth power terminal.

9. The semiconductor device according to claim 8, wherein in the first semiconductor module,
the first power terminal is joined on a lower surface of the first conductor plate, the lower surface of the first conductor plate being opposed to the second conductor plate, and
the second conductor plate comprises a notch at a region opposed to the first power terminal.

10. The semiconductor device according to claim 8, wherein in the second semiconductor module,
the third power terminal is joined on a lower surface of the third conductor plate, the lower surface of the third conductor plate being opposed to the fourth conductor plate, and
the fourth conductor plate comprises a notch at a region opposed to the third power terminal.

11. The semiconductor device according to claim 8, wherein at least one of the first conductor plate and the second conductor plate of the first semiconductor module comprises an opening located between either the first power terminal or the second power terminal and the at least one first semiconductor element.

12. The semiconductor device according to claim 8, wherein at least one of the third conductor plate and the fourth conductor plate of the second semiconductor module comprises an opening located between either the third power terminal or the fourth power terminal and the at least one second semiconductor element.

13. The semiconductor device according to claim 1, wherein each of the at least one first semiconductor element and the at least one second semiconductor element is a switching element.

14. The semiconductor device according to claim 1, wherein
each of the at least one first semiconductor element and the at least one second semiconductor element is an insulated gate bipolar transistor (IGBT) or a metal-oxide-semiconductor field-effect transistor (MOSFET), and
each of the upper electrodes of the at least one first semiconductor element and the at least one second semiconductor element is an emitter electrode of the IGBT or a source electrode of the MOSFET, and
each of the lower electrodes of the at least one first semiconductor element and the at least one second semiconductor element is a collector electrode of the IGBT or a drain electrode of the MOSFET.
